(19) United States
(12) Patent Application Publication
(10) Pub. No.: US 2025/0218346 A1
(43) Pub. Date: Jul. 3, 2025

(54) DISPLAY PIXEL CIRCUIT USING FERROELECTRIC THIN FILM TRANSISTOR AND DRIVING METHOD THEREOF

(71) Applicant: UNIVERSITY-INDUSTRY COOPERATION GROUP OF KYUNG HEE UNIVERSITY, Yongin-si, Gyeonggi-do (KR)

(72) Inventors: Jin JANG, Seoul (KR); Jun Yeong KIM, Goyang-si (KR)

(73) Assignee: UNIVERSITY-INDUSTRY COOPERATION GROUP OF KYUNG HEE UNIVERSITY, Yongin-si, Gyeonggi-do (KR)

(21) Appl. No.: 18/848,581

(22) PCT Filed: Aug. 11, 2022
(86) PCT No.: PCT/KR2022/011974

§ 371 Date: Sep. 19, 2024

(30) Foreign Application Priority Data
May 4, 2022 (KR) 10-2022-0055194

(51) Int. Cl. G09G 3/32; G09G 3/3225

(52) U.S. Cl. CPC G09G 3/32; G09G 3/3225; G09G 2310/08; G09G 2320/064

(57) ABSTRACT

The present invention relates to a display pixel circuit using ferroelectric thin-film transistors and a method of driving the same. More particularly, the present invention relates to a display pixel circuit in which a volatile switch function and a non-volatile memory function are selectively applied by using a plurality of ferroelectric thin-film transistors including a ferroelectric gate-insulating film having a high dielectric constant (high-k) and a method of driving the display pixel circuit.

### TECHNICAL FIELD

The present invention relates to a display pixel circuit using ferroelectric thin-film transistors and a method of driving the same. More particularly, the present invention relates to a display pixel circuit in which a volatile switch function and a non-volatile memory function are selectively applied by using a plurality of ferroelectric thin-film transistors including a ferroelectric gate-insulating film having a high dielectric constant (high-k) and a method of driving the display pixel circuit.

### BACKGROUND ART

A unit pixel circuit used in actively driven displays such as adaptive matrix organic LED (AMOLED) and adaptive mini LED (AMLED) includes a plurality of transistors and a capacitor.

The transistor operates as a switch transistor or driving transistor so that the light-emitting element of each pixel emits light.

In addition, the capacitor plays the role of storing charge to maintain the light-emitting state of a specific pixel per frame.

Recently, resolutions of 400 ppi (pixels per inch) or higher have been adopted in mobile displays, and AR/VR displays require resolutions of several thousand ppi or more.

To increase resolution, the size of a unit pixel that drives a display must be reduced.

However, there are difficulties in reducing the number and size of transistors and capacitors that make up pixels.

In addition, capacitors have the disadvantage of taking up a large area within a circuit that constitutes a unit pixel.

### DISCLOSURE

### Technical Problem

Therefore, the present invention has been made in view of the above problems, and it is one object of the present invention to reduce the area of a display pixel circuit by removing a capacitor that occupies a large area of a display unit pixel by simultaneously performing the roles of a switch element and a memory element using a plurality of ferroelectric thin-film transistors.

It is another object of the present invention to implement an ultra-high resolution display by replacing the role of a capacitor in a display pixel circuit and reducing the size of the display pixel circuit by adopting a dual gate structure for each of a plurality of ferroelectric thin-film transistors and selectively using a volatile switch function and a non-volatile memory function.

It is yet another object of the present invention to provide a display pixel circuit in which a volatile switch function and a non-volatile memory function are selectively applied by using a plurality of ferroelectric thin-film transistors including a ferroelectric gate-insulating film having a high dielectric constant (high-k) and a method of driving the display pixel circuit.

### Technical Solution

In accordance with one aspect of the present invention, provided is a display pixel circuit including a first thin-film transistor, a second thin-film transistor, and a light-emitting element, wherein a first gate electrode of the first thin-film transistor is connected to a first scan line, a second gate electrode is connected to a ground terminal, a drain electrode is connected to a data line, and a source electrode is connected to a second gate electrode of the second thin-film transistor; a first gate electrode of the second thin-film transistor is connected to any one of a second scan line and a third scan line, a drain electrode is connected to a first power voltage, and a source electrode is connected to a positive electrode of the light-emitting element; the first thin-film transistor has ferroelectric properties based on a gate-insulating film associated with at least one of the first and second gate electrodes of the first thin-film transistor; the second thin-film transistor has ferroelectric properties based on a gate-insulating film associated with at least one of the first and second gate electrodes of the second thin-film transistor; a negative electrode of the light-emitting element is connected to a second power voltage; and brightness of the light-emitting element is controlled based on signals transmitted through the first scan line, the second scan line, the third scan line, and the data line and the first power voltage.

Any one of the first thin-film transistor and the second thin-film transistor may include a substrate; a buffer-insulating film formed on the substrate; a first gate electrode formed on the buffer-insulating film; a first gate-insulating film formed on the first gate electrode; a semiconductor layer formed on the first gate-insulating film; a second gate-insulating film formed on the semiconductor layer; a second gate electrode formed on the second gate-insulating film; an interlayer insulating film formed on the second gate electrode, the semiconductor layer, and the first gate-insulating film to expose a source region and drain region of the semiconductor layer; a source electrode formed on the interlayer insulating film and electrically connected to the source region; and a drain electrode formed on the interlayer insulating film and electrically connected to the drain region.

The first gate-insulating film may be formed of a non-ferroelectric material including silicon dioxide (SiO₂) or a ferroelectric material including at least one of hafnium oxide (HfOₓ), hafnium zirconium oxide (HZO), and zirconium oxide (ZrOₓ), and the second gate-insulating film may be formed of a ferroelectric material including at least one of hafnium oxide (HfOₓ), hafnium zirconium oxide (HZO), and zirconium oxide (ZrOₓ).

The second gate-insulating film may be formed of a non-ferroelectric material including silicon dioxide (SiO₂) or a ferroelectric material including at least one of hafnium oxide (HfOₓ), hafnium zirconium oxide (HZO), and zirconium oxide (ZrOₓ), and the first gate-insulating film may be formed of a ferroelectric material including at least one of hafnium oxide (HfOₓ), hafnium zirconium oxide (HZO), and zirconium oxide (ZrOₓ).

A second gate electrode of the first thin-film transistor may be connected to the ground terminal to remove ferroelectric properties of a second gate-insulating film of the first thin-film transistor, and thus the first thin-film transistor may have no memory characteristics and may operate as a volatile switching thin-film transistor; and a second gate electrode of the second thin-film transistor may be connected to a source electrode of the first thin-film transistor so that the second thin-film transistor has non-volatile memory characteristics due to ferroelectric properties of a second gate-insulating film of the second thin-film transistor, and thus the second thin-film transistor may operate as a non-volatile driving thin-film transistor.

In the second thin-film transistor, one frame may be divided into a plurality of sub-frames and a luminous state of the light-emitting element in which brightness of the light-emitting element is controlled may be maintained for the one frame based on the non-volatile memory characteristics.

The number of operating sub-frames may be determined depending on time when the first power voltage is applied as a high voltage in the sub-frames, and brightness of the light-emitting element may increase as the determined number of sub-frames increases.

Charges stored in the second thin-film transistor may be reset based on a signal applied through any one of the second scan line and the third scan line.

An on or off state of the first thin-film transistor may be controlled based on a signal applied through the first scan line.

When the first thin-film transistor is in an on state, an on or off state of the second thin-film transistor may be controlled based on a signal of the data line.

The signal of the data line may consist of any one of a low-voltage signal and high-voltage signal that determines whether the second thin-film transistor is turned on or off.

In accordance with another aspect of the present invention, provided is a method of driving a display pixel circuit, wherein the display pixel circuit includes a first thin-film transistor in which a first gate electrode of the first thin-film transistor is connected to a first scan line, a second gate electrode is connected to a ground terminal, a drain electrode is connected to a data line, and a source electrode is connected to a second gate electrode of a second thin-film transistor; the second thin-film transistor in which a first gate electrode of the second thin-film transistor is connected to any one of a second scan line and a third scan line, a drain electrode is connected to a first power voltage, and a source electrode is connected to a positive electrode of a light-emitting element; and the light-emitting element in which a negative electrode of the light-emitting element is connected to a second power voltage, wherein the first thin-film transistor has ferroelectric properties based on a gate-insulating film associated with at least one of the first and second gate electrodes of the first thin-film transistor; and the second thin-film transistor has ferroelectric properties based on a gate-insulating film associated with at least one of the first and second gate electrodes of the second thin-film transistor, and the method includes a step of controlling brightness of the light-emitting element based on signals transmitted through the first scan line, the second scan line, the third scan line, and the data line and the first power voltage.

The step of controlling brightness of the light-emitting element based on signals transmitted through the first scan line, the second scan line, the third scan line, and the data line and the first power voltage may include a step of resetting charges stored in the second thin-film transistor based on a signal applied through any one of the second scan line and the third scan line; a step of controlling an on or off state of the first thin-film transistor based on a signal applied through the first scan line; a step of controlling an on or off state of the second thin-film transistor and emission of the light-emitting element based on a signal of the data line when the first thin-film transistor is in an on state; and a step of controlling brightness of the light-emitting element based on time when the first power voltage is applied as a high voltage when the second thin-film transistor is in an on state.

The step of controlling brightness of the light-emitting element based on time when the first power voltage is applied as a high voltage when the second thin-film transistor is in an on state may include
a step of dividing one frame related to brightness of the light-emitting element into a plurality of sub-frames, determining the number of sub-frames operated by controlling time when the first power voltage is applied as a high voltage, and controlling brightness of the light-emitting element according to the determined number of sub-frames.

In accordance with yet another aspect of the present invention, provided is a method of driving a display pixel circuit using pulse width modulation (PWM) driving based on a plurality of driving elements, wherein each of the driving elements includes a first gate electrode and a second gate electrode and has a dual gate structure, wherein at least one of a first gate-insulating film of the first gate electrode and a second gate-insulating film of the second gate electrode is formed of a ferroelectric material and has ferroelectric properties, and the method includes a step of removing ferroelectric properties from any one of the driving elements based on a ground voltage to drive the driving element as a volatile switching element and drive another driving element as a non-volatile driving element based on ferroelectric properties.

The first gate-insulating film may be formed of a non-ferroelectric material including silicon dioxide (SiO₂) or a ferroelectric material including at least one of hafnium oxide (HfOₓ), hafnium zirconium oxide (HZO), and zirconium oxide (ZrOₓ), and the second gate-insulating film may be formed of a non-ferroelectric material including silicon dioxide (SiO₂) or a ferroelectric material including at least one of hafnium oxide (HfOₓ), hafnium zirconium oxide (HZO), and zirconium oxide (ZrOₓ).

The driving elements may include a first thin-film transistor and a second thin-film transistor.

A second gate electrode of the first thin-film transistor may be connected to a ground terminal to remove ferroelectric properties of a second gate-insulating film of the first thin-film transistor based on the ground voltage, and thus the first thin-film transistor may have no memory characteristics and operate as the volatile switching element; and a second gate electrode of the second thin-film transistor may be connected to a source electrode of the first thin-film transistor so that the second thin-film transistor has non-volatile memory characteristics due to ferroelectric properties of a second gate-insulating film of the second thin-film transistor, and thus the second thin-film transistor may operate as the non-volatile driving thin-film transistor.

### Advantageous Effects

The present invention can reduce the area of a display pixel circuit by removing a capacitor that occupies a large area of a display unit pixel by simultaneously performing the roles of a switch element and a memory element using a plurality of ferroelectric thin-film transistors.

The present invention can implement an ultra-high resolution display by replacing the role of a capacitor in a display pixel circuit and reducing the size of the display pixel circuit by adopting a dual gate structure for each of a plurality of ferroelectric thin-film transistors and selectively using a volatile switch function and a non-volatile memory function.

The present invention can provide a display pixel circuit in which a volatile switch function and a non-volatile memory function are selectively applied by using a plurality of ferroelectric thin-film transistors including a ferroelectric gate-insulating film having a high dielectric constant (high-k) and a method of driving the display pixel circuit.

### DESCRIPTION OF DRAWINGS

FIGS. 1A and 1B are diagrams explaining a display pixel circuit according to an embodiment of the present invention.

FIGS. 2A and 2B are diagrams explaining signal changes related to the operation of the display pixel circuit according to an embodiment of the present invention.

FIG. 3 is a diagram explaining a ferroelectric thin-film transistor according to an embodiment of the present invention.

FIG. 4 is a flowchart explaining a method of manufacturing the ferroelectric thin-film transistor according to an embodiment of the present invention.

FIG. 5 is a diagram explaining the operating characteristics of the ferroelectric thin-film transistor according to an embodiment of the present invention.

FIG. 6 is a flowchart explaining a method of driving the display pixel circuit according to an embodiment of the present invention.

### BEST MODE

Hereinafter, the embodiments of the present invention will be described in detail with reference to the drawings.

However, it should be understood that the present invention is not limited to the embodiments according to the concept of the present invention, but includes changes, equivalents, or alternatives falling within the spirit and scope of the present invention.

In the following description of the present invention, detailed description of known functions and configurations incorporated herein will be omitted when it may make the subject matter of the present invention unclear.

In addition, the terms used in the specification are defined in consideration of functions used in the present invention, and can be changed according to the intent or conventionally used methods of clients, operators, and users. Accordingly, definitions of the terms should be understood on the basis of the entire description of the present specification.

In description of the drawings, like reference numerals may be used for similar elements.

The singular expressions in the present specification may encompass plural expressions unless clearly specified otherwise in context.

In this specification, expressions such as “A or B” and “at least one of A and/or B” may include all possible combinations of the items listed together.

Expressions such as “first” and “second” may be used to qualify the elements irrespective of order or importance, and are used to distinguish one element from another and do not limit the elements.

It will be understood that when an element (e.g., first) is referred to as being “connected to” or “coupled to” another element (e.g., second), the first element may be directly connected to the second element or may be connected to the second element via an intervening element (e.g., third).

As used herein, “configured to” may be used interchangeably with, for example, “suitable for”, “ability to”, “changed to”, “made to”, “capable of”, or “designed to” in terms of hardware or software.

In some situations, the expression “device configured to” may mean that the device “may do˜” with other devices or components.

For example, in the sentence “processor configured to perform A, B, and C”, the processor may refer to a general purpose processor (e.g., CPU or application processor) capable of performing corresponding operation by running a dedicated processor (e.g., embedded processor) for performing the corresponding operation, or one or more software programs stored in a memory device.

In addition, the expression “or” means “inclusive or” rather than “exclusive or”.

That is, unless mentioned otherwise or clearly inferred from context, the expression “x uses a or b” means any one of natural inclusive permutations.

Terms, such as “unit” or “module”, etc., should be understood as a unit that processes at least one function or operation and that may be embodied in a hardware manner, a software manner, or a combination of the hardware manner and the software manner.

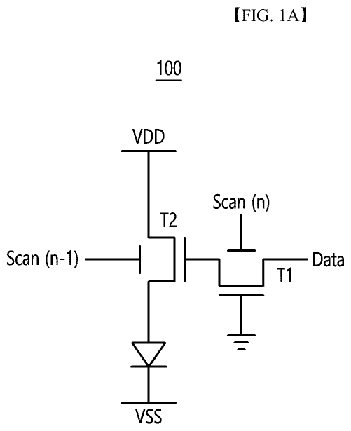

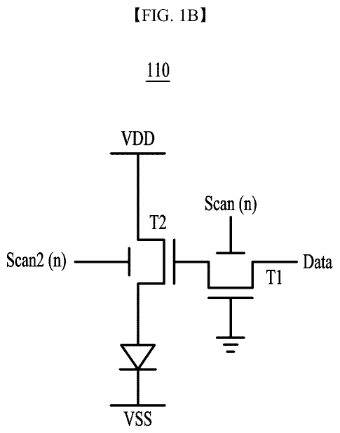

FIGS. 1A and 1B are diagrams explaining a display pixel circuit according to an embodiment of the present invention.

FIGS. 1A and 1B illustrate the structure of a display pixel circuit including a first thin-film transistor, a second thin-film transistor, and a light-emitting element according to an embodiment of the present invention.

A display pixel circuit 100 in FIG. 1A and a display pixel circuit 110 in FIG. 1B have the same connection structure except that there is a difference in the signal of a scan line applied through the first gate electrode of a second thin-film transistor T2.

More specifically, in the display pixel circuit 100, the signal of the second scan line (Scan (n-1)) is applied through the first gate electrode, and in the display pixel circuit 110, the signal of the third scan line (Scan2 (n)) is applied through the first gate electrode.

Accordingly, the connection structure of the display pixel circuit 100 is explained based on the display pixel circuit 100, but the display pixel circuit 110 may also have the same connection structure as the display pixel circuit 100.

For example, the display pixel circuit 100 may be designed to have at least two thin-film transistors without a capacitor.

A first power voltage (VDD), a second power voltage (VSS), and a data signal may be applied through an external circuit.

According to an embodiment of the present invention, the display pixel circuit 100 includes the first thin-film transistor T1, the second thin-film transistor T2, and the light-emitting element. Here, the light-emitting element is expressed with a diode symbol.

In the display pixel circuit 100, the first gate electrode of the first thin-film transistor T1 is connected to the first scan line (Scan (n)), the second gate electrode is connected to the ground terminal, the drain electrode is connected to the data line (Data), and the source electrode is connected to the second gate electrode of the second thin-film transistor T2.

In addition, the first gate electrode of the second thin-film transistor T2 is connected to the second scan line (Scan (n-1)). Here, when connected to the third scan line (Scan2 (n)), the case is the display pixel circuit 110. The drain electrode is connected to the first power voltage (VDD), the source electrode is connected to the positive electrode of the light-emitting element, and the negative electrode of the light-emitting element is connected to the second power voltage (VSS).

For example, the first thin-film transistor T1 may have ferroelectric properties based on a gate-insulating film associated with at least one gate electrode of the first gate electrode and second gate electrode of the first thin-film transistor T1.

According to an embodiment of the present invention, the second thin-film transistor T2 may have ferroelectric properties based on a gate-insulating film associated with at least one gate electrode of the first gate electrode and second gate electrode of the second thin-film transistor T2.

For example, the gate-insulating film related to the first gate electrode may be a first gate-insulating film, and the gate-insulating film related to the second gate electrode may be a second gate-insulating film. For example, the ferroelectric properties may refer to ferroelectricity.

That is, in each of the first thin-film transistor Tl and the second thin-film transistor, at least one gate-insulating film of the first gate-insulating film and the second gate-insulating film may be formed of a ferroelectric material.

That is, both the first gate-insulating film and the second gate-insulating film may be formed of a ferroelectric material, the first gate-insulating film may be formed of a ferroelectric material and the second gate-insulating film may be formed of a non-ferroelectric material, or the first gate-insulating film may be formed of a non-ferroelectric material and the second gate-insulating film may be formed of a ferroelectric material.

According to an embodiment of the present invention, the first thin-film transistor T1 and the second thin-film transistor T2 have a second gate-insulating film located between the second gate electrode and a semiconductor layer. Since the second gate-insulating film is formed of a ferroelectric material, the first thin-film transistor Tl and the second thin-film transistor T2 may selectively operate as a volatile switching thin-film transistor or a non-volatile driving thin-film transistor.

For example, since the second gate electrode of the first thin-film transistor T1 is connected to the ground terminal and the ferroelectric properties of the second gate-insulating film of the first thin-film transistor Tl are removed, the first thin-film transistor T1 has no memory characteristics and may operate as a volatile switching thin-film transistor.

According to an embodiment of the present invention, since the second gate electrode of the second thin-film transistor T2 is connected to the source electrode of the first thin-film transistor T1 and the second gate-insulating film of the second thin-film transistor T2 has ferroelectric properties, the second thin-film transistor T2 has non-volatile memory characteristics and may operate as a non-volatile driving thin-film transistor.

That is, the first thin-film transistor T1 may be a volatile switching thin-film transistor, and the second thin-film transistor T2 may be a non-volatile driving thin-film transistor. Accordingly, the second thin-film transistor T2 may operate as a capacitor.

In addition, the second thin-film transistor T2 may maintain the luminous state of the light-emitting element for one frame based on non-volatile memory characteristics.

For example, one frame may be divided into a plurality of sub-frames, and the sub-frames may be related to brightness control of the light-emitting element depending on the number of operating sub-frames.

As the number of operating sub-frames increases among a plurality of sub-frames, the brightness of the light-emitting element may increase.

According to an embodiment of the present invention, the display pixel circuit may operate without a capacitor by using a pulse width modulation (PWM) driving method using at least two thin-film transistors in AMLED/AMOLED driving.

In addition, a PWM signal used in the PWM driving method may be controlled by first power voltage (VDD) or second power voltage (VSS).

For example, the display pixel circuit is a display pixel circuit based on an AMOLED/AMLED array design using pulse width modulation (PWM) driving. The driving element has a dual gate structure including upper and lower gate electrodes, and at least one of the insulating film of the upper gate electrode and the insulating film of the lower gate electrode consists of a thin-film transistor that is a ferroelectric material.

According to an embodiment of the present invention, in a method of driving a display pixel circuit using PWM driving based on a plurality of driving elements, each of the driving elements may have a dual gate structure including a first gate electrode and a second gate electrode.

In addition, at least one gate-insulating film among the first gate-insulating film of the first gate electrode and the second gate-insulating film of the second gate electrode may be formed of a ferroelectric material and have ferroelectric properties.

For example, the first gate electrode may be a lower electrode and the second gate electrode may be an upper electrode.

For example, a method of driving a display pixel circuit may include a step of removing ferroelectric properties from any one of a plurality of driving elements based on a ground voltage to drive the driving element as a volatile switching element and drive another driving element as a non-volatile driving element based on ferroelectric properties.

For example, the first gate-insulating film may be formed of a non-ferroelectric material including silicon dioxide (SiO₂) or a ferroelectric material including at least one of hafnium oxide (HfOₓ), hafnium zirconium oxide (HZO), and zirconium oxide (ZrOₓ).

In addition, the second gate-insulating film may be formed of a non-ferroelectric material including silicon dioxide (SiO₂) or a ferroelectric material including at least one of hafnium oxide (HfOₓ), hafnium zirconium oxide (HZO), and zirconium oxide (ZrOₓ).

For example, a plurality of driving elements may include the first thin-film transistor and the second thin-film transistor.

Since the second gate electrode of the first thin-film transistor is connected to the ground terminal and the ferroelectric properties of the second gate-insulating film of the first thin-film transistor are removed based on a ground voltage, the first thin-film transistor has no memory characteristics and may operate as a volatile switching element.

In addition, since the second gate electrode of the second thin-film transistor is connected to the source electrode of the first thin-film transistor and the second gate-insulating film of the second thin-film transistor has ferroelectric properties, the second thin-film transistor has non-volatile memory characteristics and may operate as a non-volatile driving element. Accordingly, the present invention may reduce the area of a display pixel circuit by removing a capacitor that occupies a large area of a display unit pixel by simultaneously performing the roles of a switch element and a memory element using a plurality of ferroelectric thin-film transistors.

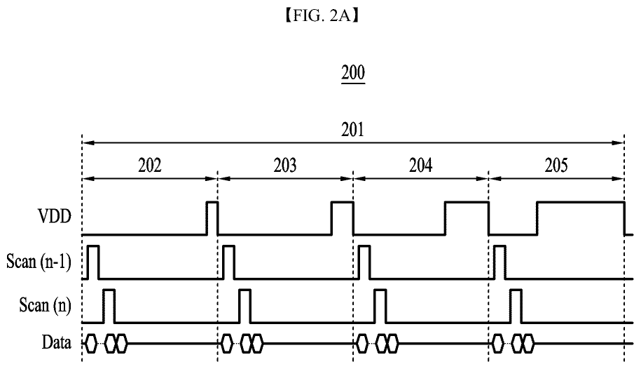

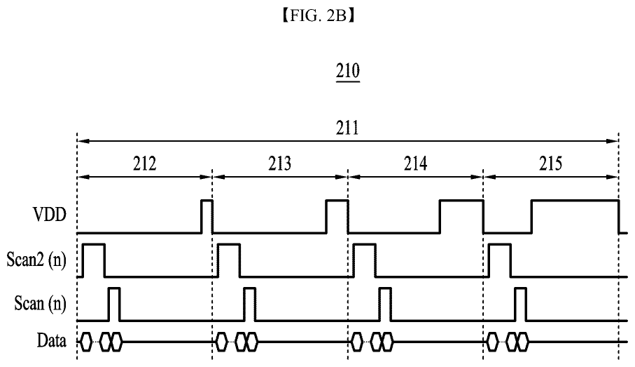

FIGS. 2A and 2B are diagrams explaining signal changes related to the operation of the display pixel circuit according to an embodiment of the present invention.

FIG. 2A illustrates a timing diagram related to the operation of the display pixel circuit 100 according to FIG. 1A according to an embodiment of the present invention, and FIG. 2B illustrates a timing diagram related to the operation of the display pixel circuit 110 according to FIG. 1B according to an embodiment of the present invention.

Referring to FIG. 2A, in a timing diagram 200, one frame 201 may consist of a plurality of sub-frames, and the sub-frames may consist of a first sub-frame 202, a second sub-frame 203, a third sub-frame 204, and a fourth sub-frame 205.

The first sub-frame 202 to the fourth sub-frame 205 is related to the brightness of the light-emitting element, and the brightness of the light-emitting element according to the fourth sub-frame 205 is greater compared to the brightness of the light-emitting element according to the first sub-frame 202.

That is, the frame 201 may be divided into sub-frames to include the first sub-frame 202 to the fourth sub-frame 205. In the case of power voltage (VDD) in the first sub-frame 202, only the portion corresponding to the first sub-frame 202 becomes bright.

In the case of power voltage (VDD) in the second sub-frame 203, only the portions corresponding to the first sub-frame 202 and the second sub-frame 203 become bright.

In the case of power voltage (VDD) in the third sub-frame 204, only the portions corresponding to the first sub-frame 202 to the third sub-frame 204 become bright.

In the case of power voltage (VDD) in the fourth sub-frame 205, only the portions corresponding to the first sub-frame 202 to the fourth sub-frame 205 become bright.

That is, in the case of power voltage (VDD) in the fourth sub-frame 205, all light-emitting elements in the frame 201 become bright, so the brightness of the light-emitting elements may be relatively increased.

The pulse width of the power voltage (VDD) may be related to the time when the power voltage (VDD) is applied as a high voltage.

That is, the number of operating sub-frames may be determined depending on the time when the power voltage (VDD) is applied as a high voltage in the first sub-frame 202 to the fourth sub-frame 205, and the brightness of the light-emitting element may increase as the determined number of sub-frames increases.

For example, the signal of a data line may consist of either a low-voltage signal or a high-voltage signal that determines whether the second thin-film transistor is turned on or off.

When the signal of the second scan line (Scan (n-1)) is applied at high voltage, charge stored in the second thin-film transistor is reset. When the signal of the first scan line (Scan (n)) is applied at high voltage, the first thin-film transistor is turned on, data is input to the second thin-film transistor through the data line connected to the first thin-film transistor, the second thin-film transistor is turned on based on the input data, the light-emitting element begins to emit light, and the luminous intensity of the light-emitting element is controlled based on the power voltage (VDD).

That is, the first thin-film transistor operates as a switching transistor, and the second thin-film transistor operates as a memory transistor. Accordingly, when the high voltage application time of the power voltage (VDD) is adjusted, the brightness of the light-emitting element may be controlled without a capacitor.

According to an embodiment of the present invention, in the second thin-film transistor, one frame is divided into a plurality of sub-frames, and the luminous state of the light-emitting element whose brightness is controlled may be maintained for one frame based on non-volatile memory characteristics.

Referring to FIG. 2B, in a timing diagram 210, one frame 211 may consist of a plurality of sub-frames, and the sub-frames may consist of the first sub-frame 212, a second sub-frame 213, a third sub-frame 214, and a fourth sub-frame 215.

The difference between the timing diagram 200 and the timing diagram 210 is that there is a difference in the pulse widths of the signal of the second scan line (Scan (n-1)) and the signal of the third scan line (Scan2 (n)), but the rest is the same.

However, there is some difference in the application timing of the first scan line (Scan (n)) depending on the signal of the third scan line (Scan2 (n)).

Since the pulse width of the signal in the timing diagram 210 and the signal of the third scan line (Scan2 (n)) is wider compared to the pulse width of the signal in the timing diagram 200 and the signal of the second scan line (Scan (n-1)), charge stored in the second thin-film transistor, which has non-volatile memory characteristics, may be reset more stably.

That is, the pulse width of the signal of the third scan line (Scan2 (n)) is wider than that of the signal of the first scan line (Scan (n)). Accordingly, when the pulse width of the signal for resetting and the pulse width of the signal for turning on the first thin-film transistor are the same, reset operation may be performed more stably.

According to an embodiment of the present invention, the second thin-film transistor T2 may reset charges stored in the second thin-film transistor based on a signal applied through any one of the second scan line and the third scan line.

For example, the on or off state of the first thin-film transistor T1 may be controlled based on a signal applied through the first scan line.

According to an embodiment of the present invention, when the first thin-film transistor is in on state, the on or off state of the second thin-film transistor may be controlled based on the signal of the data line.

Accordingly, the present invention may implement an ultra-high resolution display by replacing the role of capacitor in a display pixel circuit and reducing the size of the display pixel circuit by adopting a dual gate structure for each of a plurality of ferroelectric thin-film transistors and selectively using a volatile switch function and a non-volatile memory function display.

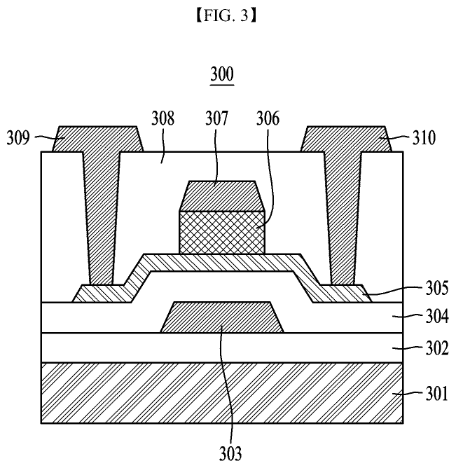

FIG. 3 is a diagram explaining a ferroelectric thin-film transistor according to an embodiment of the present invention.

FIG. 3 illustrates the structure of a ferroelectric thin-film transistor according to an embodiment of the present invention.

Referring to FIG. 3, a ferroelectric thin-film transistor 300 according to an embodiment of the present invention includes a substrate 301, a buffer-insulating film 302 formed on the substrate 301, a first gate electrode 303 formed on the buffer-insulating film 302, and a first gate-insulating film 304 formed on the first gate electrode 303.

In addition, the ferroelectric thin-film transistor 300 includes a semiconductor layer 305 formed on the first gate-insulating film 304, a second gate-insulating film 306 formed on the semiconductor layer 305, and a second gate electrode 307 formed on the second gate-insulating film 306.

In addition, the ferroelectric thin-film transistor 300 includes an interlayer insulating film 308 formed on the second gate electrode 307, the semiconductor layer 305, and the first gate-insulating film 304 to expose the source and drain regions of the semiconductor layer 305.

In addition, the ferroelectric thin-film transistor 300 includes a source electrode 309 formed on the interlayer insulating film 308 and electrically connected to the source region and a drain electrode 310 formed on the interlayer insulating film 308 and electrically connected to the drain region.

The positions of the source electrode 309 and the drain electrode 310 may change depending on the settings of the source and drain regions.

According to an embodiment of the present invention, the first gate-insulating film 304 may be formed of a non-ferroelectric material including silicon dioxide (SiO₂) or a ferroelectric material including at least one of hafnium oxide (HfOₓ), hafnium zirconium oxide (HZO), and zirconium oxide (ZrOₓ).

For example, the second gate-insulating film 306 may be formed of a ferroelectric material including at least one of hafnium oxide (HfOₓ), hafnium zirconium oxide (HZO), and zirconium oxide (ZrOₓ).

In addition, the second gate-insulating film 306 may be formed of a non-ferroelectric material including or a ferroelectric material including at least one of hafnium oxide (HfOₓ), hafnium zirconium oxide (HZO), and zirconium oxide (ZrOₓ), and the first gate-insulating film 304 may be formed of a ferroelectric material including at least one of hafnium oxide (HfOₓ), hafnium zirconium oxide (HZO), and zirconium oxide (ZrOₓ).

For example, when at least one of the first gate-insulating film 304 and the second gate-insulating film 306 is formed of a ferroelectric material, a multilayer structure may be formed in which at least one hafnium oxide (HfOₓ), hafnium zirconium oxide (HZO), and zirconium oxide (ZrOₓ) is sequentially laminated.

In addition, when at least one of the first gate-insulating film 304 and the second gate-insulating film 306 is formed of a ferroelectric material, aluminum oxide (AlOₓ) may be used as a component that promotes at least one of the first gate-insulating film 304 and the second gate-insulating film 306 to have ferroelectric properties.

The substrate 301 may be a semiconductor substrate, and the buffer-insulating film 302 may be formed of an insulating material.

The first gate electrode 303 and the second gate electrode 307 may be formed of a metal material, and a dual gate may be configured in which the first gate electrode 303 is a lower electrode (bottom gate) and the second gate electrode 307 is an upper electrode (top gate).

The semiconductor layer 305 is an oxide semiconductor layer and may be formed using poly-Si, an oxide (IGZO, IGO, ZNO, etc.), or an inorganic material.

The ferroelectric thin-film transistor 300 may include the first gate-insulating film 304 and the second gate-insulating film 306 having ferroelectricity. The ferroelectric thin-film transistor 300 is a dual gate structure and may be selectively used as a display-driving thin-film transistor or switching transistor in AMOLED/AMLED driving.

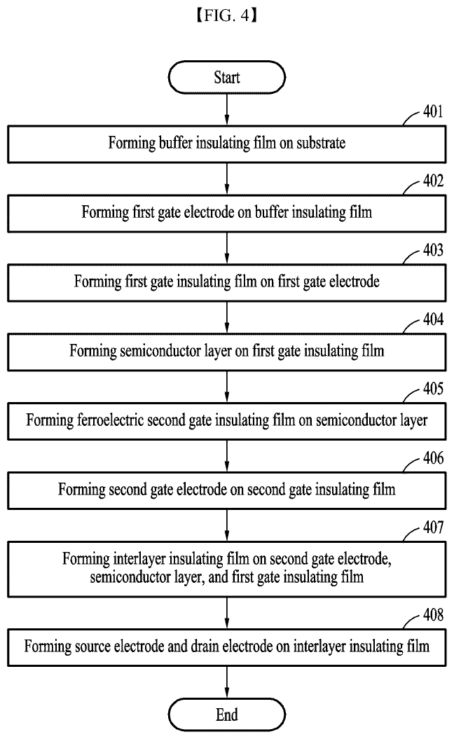

FIG. 4 is a flowchart explaining a method of manufacturing the ferroelectric thin-film transistor according to an embodiment of the present invention.

FIG. 4 illustrates a method of manufacturing a ferroelectric thin-film transistor according to an embodiment of the present invention.

Referring to FIG. 4, in step 401, according to the method of manufacturing a ferroelectric thin-film transistor, a buffer-insulating film is formed on a substrate.

That is, according to the method of manufacturing a ferroelectric thin-film transistor, the buffer-insulating film may be formed on the substrate through a spray process.

In step 402, according to the method of manufacturing a ferroelectric thin-film transistor, a first gate electrode is formed on the buffer-insulating film.

In step 403, according to the method of manufacturing a ferroelectric thin-film transistor, a first gate-insulating film is formed on the first gate electrode.

That is, according to the method of manufacturing a ferroelectric thin-film transistor, the first gate-insulating film is formed on the first gate electrode through a spray process.

In step 404, according to the method of manufacturing a ferroelectric thin-film transistor, a semiconductor layer is formed on the first gate-insulating film.

That is, according to the method of manufacturing a ferroelectric thin-film transistor, the semiconductor layer is formed on the first gate-insulating film through a spray process.

For example, the first gate-insulating film may be formed of a non-ferroelectric material including silicon dioxide (SiO₂) or a ferroelectric material including at least one of hafnium oxide (HfOₓ), hafnium zirconium oxide (HZO), and zirconium oxide (ZrOₓ).

In step 405, according to the method of manufacturing a ferroelectric thin-film transistor, a ferroelectric second gate-insulating film is formed on the semiconductor layer.

That is, according to the method of manufacturing a ferroelectric thin-film transistor, the second gate-insulating film is formed on the semiconductor layer through a spray process.

In step 406, according to the method of manufacturing a ferroelectric thin-film transistor, a second gate electrode is formed on the second gate-insulating film.

In step 407, according to the method of manufacturing a ferroelectric thin-film transistor, an interlayer insulating film is formed on the second gate electrode, the semiconductor layer, and the first gate-insulating film.

In step 408, according to the method of manufacturing a ferroelectric thin-film transistor, a source electrode and a drain electrode are formed on the interlayer insulating film.

According to an embodiment of the present invention, according to the method of manufacturing a ferroelectric thin-film transistor, a ferroelectric material including at least one of hafnium oxide (HfOₓ), hafnium zirconium oxide (HZO), and zirconium oxide (ZrOₓ) is applied at about 350°° C. through a spray process, and a rapid thermal annealing (RTA) process is performed at 650°° C. for 3 minutes to form a second gate-insulating film formed of a ferroelectric material including at least one of hafnium oxide (HfOₓ), hafnium zirconium oxide (HZO), and zirconium oxide (ZrOₓ) on the semiconductor layer and manufacture a thin-film transistor having ferroelectricity.

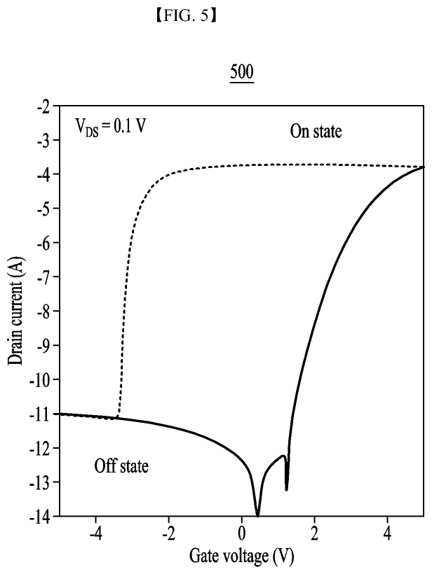

FIG. 5 is a diagram explaining the operating characteristics of the ferroelectric thin-film transistor according to an embodiment of the present invention.

FIG. 5 shows a graph for explaining the ferroelectricity of the ferroelectric thin-film transistor according to an embodiment of the present invention.

Referring to FIG. 5, in graph 500, the horizontal axis represents changes in gate voltage and the vertical axis represents changes in drain current.

The solid line represents a forward sweep state, and the dotted line represents a reverse sweep state.

Comparing the solid line and the dotted line, it can be seen that the threshold voltage (Vth) that determines the on and off states is different depending on the sweep direction.

Comparing the solid line and the dotted line, it can be seen that when a gate voltage is 0 V to −1 V, the solid line is in the off state and the dotted line is in the on state.

That is, the ferroelectric thin-film transistor may remain on or off for a long period of time.

That is, since the thin-film transistor exhibits non-volatile memory characteristics in the process of changing the charge state within the thin-film transistor, the thin-film transistor may operate as a capacitor.

Accordingly, when using the ferroelectric thin-film transistor, a display pixel circuit may be designed without a capacitor.

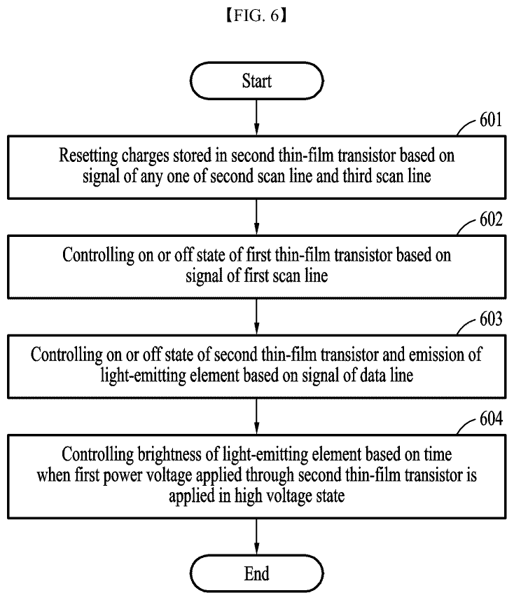

FIG. 6 is a flowchart explaining a method of driving the display pixel circuit according to an embodiment of the present invention.

FIG. 6 illustrates a method of driving a display pixel circuit in which the display pixel circuit controls brightness while emitting a light-emitting element according to an embodiment of the present invention.

Referring to FIG. 6, in step 601, according the method of driving a display pixel circuit, charges stored in the second thin-film transistor are reset based on the signal of any one of the second scan line and the third scan line.

That is, according the method of driving a display pixel circuit, to apply a data signal transmitted from the display pixel circuit to the second thin-film transistor through the first thin-film transistor, the second thin-film transistor, which has non-volatile memory characteristics, is reset.

In step 602, according the method of driving a display pixel circuit, the on or off state of the first thin-film transistor is controlled based on the signal of the first scan line.

That is, according the method of driving a display pixel circuit, when the signal of the first scan line is high voltage, the first thin-film transistor is switched to the on state to function as a switching transistor.

Here, as the first thin-film transistor is turned on, a data signal applied through the data line is transmitted to the second gate electrode of the second thin-film transistor.

In step 603, according the method of driving a display pixel circuit, based on the signal from the data line, the on or off state of the second thin-film transistor and the emission of the light-emitting element are controlled.

That is, according the method of driving a display pixel circuit, the on or off state of the second thin-film transistor is determined depending on whether the data signal is high voltage or low voltage. When the second thin-film transistor is in the on state, the first power voltage (VDD) is transmitted to the light-emitting element, causing the light-emitting element to emit light.

In step 604, according the method of driving a display pixel circuit, the brightness of the light-emitting element may be controlled based on the time when the first power voltage (VDD) applied through the second thin-film transistor is applied as a high voltage state.

That is, according the method of driving a display pixel circuit, the brightness of the light-emitting element is controlled by determining the degree to which the sub-frame within the frame operates depending on the amount of time applied as a high voltage state.

For example, the number of operating sub-frames may be determined depending on the time when the first power voltage (VDD) is applied as a high voltage in a plurality of sub-frames, and the brightness of the light-emitting element may increase as the determined number of sub-frames increases.

Accordingly, the present invention may provide a display pixel circuit in which a volatile switch function and a non-volatile memory function are selectively applied by using a plurality of ferroelectric thin-film transistors including a ferroelectric gate-insulating film having a high dielectric constant (high-k) and a method of driving the display pixel circuit.

Although the present invention has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

1. A display pixel circuit, comprising a first thin-film transistor, a second thin-film transistor, and a light-emitting element,
wherein a first gate electrode of the first thin-film transistor is connected to a first scan line, a second gate electrode is connected to a ground terminal, a drain electrode is connected to a data line, and a source electrode is connected to a second gate electrode of the second thin-film transistor;
a first gate electrode of the second thin-film transistor is connected to any one of a second scan line and a third scan line, a drain electrode is connected to a first power voltage, and a source electrode is connected to a positive electrode of the light-emitting element;
the first thin-film transistor has ferroelectric properties based on a gate-insulating film associated with at least one of the first and second gate electrodes of the first thin-film transistor;
the second thin-film transistor has ferroelectric properties based on a gate-insulating film associated with at least one of the first and second gate electrodes of the second thin-film transistor;
a negative electrode of the light-emitting element is connected to a second power voltage; and
brightness of the light-emitting element is controlled based on signals transmitted through the first scan line, the second scan line, the third scan line, and the data line and the first power voltage.

2. The display pixel circuit according to claim 1, wherein any one of the first thin-film transistor and the second thin-film transistor comprises a substrate;
a buffer-insulating film formed on the substrate;
a first gate electrode formed on the buffer-insulating film;
a first gate-insulating film formed on the first gate electrode;
a semiconductor layer formed on the first gate-insulating film;
a second gate-insulating film formed on the semiconductor layer;
a second gate electrode formed on the second gate-insulating film;
an interlayer insulating film formed on the second gate electrode, the semiconductor layer, and the first gate-insulating film to expose a source region and drain region of the semiconductor layer;
a source electrode formed on the interlayer insulating film and electrically connected to the source region; and
a drain electrode formed on the interlayer insulating film and electrically connected to the drain region.

3. The display pixel circuit according to claim 2, wherein the first gate-insulating film is formed of a non-ferroelectric material comprising silicon dioxide (SiO₂) or a ferroelectric material comprising at least one of hafnium oxide (HfOₓ), hafnium zirconium oxide (HZO), and zirconium oxide (ZrOₓ); and
the second gate-insulating film is formed of a ferroelectric material comprising at least one of hafnium oxide (HfOₓ), hafnium zirconium oxide (HZO), and zirconium oxide (ZrOₓ).

4. The display pixel circuit according to claim 2, wherein the second gate-insulating film is formed of a non-ferroelectric material comprising silicon dioxide (SiO₂) or a ferroelectric material comprising at least one of hafnium oxide (HfOₓ), hafnium zirconium oxide (HZO), and zirconium oxide (ZrOₓ); and
the first gate-insulating film is formed of a ferroelectric material comprising at least one of hafnium oxide (HfOₓ), hafnium zirconium oxide (HZO), and zirconium oxide (ZrOₓ).

5. The display pixel circuit according to claim 1, wherein a second gate electrode of the first thin-film transistor is connected to the ground terminal to remove ferroelectric properties of a second gate-insulating film of the first thin-film transistor, and thus the first thin-film transistor has no memory characteristics and operates as a volatile switching thin-film transistor; and
a second gate electrode of the second thin-film transistor is connected to a source electrode of the first thin-film transistor so that the second thin-film transistor has non-volatile memory characteristics due to ferroelectric properties of a second gate-insulating film of the second thin-film transistor, and thus the second thin-film transistor operates as a non-volatile driving thin-film transistor.

6. The display pixel circuit according to claim 5, wherein, in the second thin-film transistor, one frame is divided into a plurality of sub-frames and a luminous state of the light-emitting element in which brightness of the light-emitting element is controlled is maintained for the one frame based on the non-volatile memory characteristics.

7. The display pixel circuit according to claim 6, wherein the number of operating sub-frames is determined depending on time when the first power voltage is applied as a high voltage in the sub-frames, and brightness of the light-emitting element increases as the determined number of sub-frames increases.

8. The display pixel circuit according to claim 1, wherein charges stored in the second thin-film transistor are reset based on a signal applied through any one of the second scan line and the third scan line.

9. The display pixel circuit according to claim 8, wherein an on or off state of the first thin-film transistor is controlled based on a signal applied through the first scan line.

10. The display pixel circuit according to claim 9, wherein, when the first thin-film transistor is in an on state, an on or off state of the second thin-film transistor is controlled based on a signal of the data line.

11. The display pixel circuit according to claim 10, wherein the signal of the data line consists of any one of a low-voltage signal and high-voltage signal that determines whether the second thin-film transistor is turned on or off.

12. A method of driving a display pixel circuit, wherein the display pixel circuit comprises a first thin-film transistor in which a first gate electrode of the first thin-film transistor is connected to a first scan line, a second gate electrode is connected to a ground terminal, a drain electrode is connected to a data line, and a source electrode is connected to a second gate electrode of a second thin-film transistor; the second thin-film transistor in which a first gate electrode of the second thin-film transistor is connected to any one of a second scan line and a third scan line, a drain electrode is connected to a first power voltage, and a source electrode is connected to a positive electrode of a light-emitting element; and the light-emitting element in which a negative electrode of the light-emitting element is connected to a second power voltage,
wherein the first thin-film transistor has ferroelectric properties based on a gate-insulating film associated with at least one of the first and second gate electrodes of the first thin-film transistor; and the second thin-film transistor has ferroelectric properties based on a gate-insulating film associated with at least one of the first and second gate electrodes of the second thin-film transistor, and
the method comprises a step of controlling brightness of the light-emitting element based on signals transmitted through the first scan line, the second scan line, the third scan line, and the data line and the first power voltage.

13. The method according to claim 12, wherein any one of the first thin-film transistor and the second thin-film transistor comprises a substrate;
a buffer-insulating film formed on the substrate;
a first gate electrode formed on the buffer-insulating film;
a first gate-insulating film formed on the first gate electrode;
a semiconductor layer formed on the first gate-insulating film;
a second gate-insulating film formed on the semiconductor layer;
a second gate electrode formed on the second gate-insulating film;
an interlayer insulating film formed on the second gate electrode, the semiconductor layer, and the first gate-insulating film to expose a source region and drain region of the semiconductor layer;
a source electrode formed on the interlayer insulating film and electrically connected to the source region; and
a drain electrode formed on the interlayer insulating film and electrically connected to the drain region.

14. The method according to claim 12, wherein the step of controlling brightness of the light-emitting element based on signals transmitted through the first scan line, the second scan line, the third scan line, and the data line and the first power voltage comprises a step of resetting charges stored in the second thin-film transistor based on a signal applied through any one of the second scan line and the third scan line;
a step of controlling an on or off state of the first thin-film transistor based on a signal applied through the first scan line;
a step of controlling an on or off state of the second thin-film transistor and emission of the light-emitting element based on a signal of the data line when the first thin-film transistor is in an on state; and
a step of controlling brightness of the light-emitting element based on time when the first power voltage is applied as a high voltage when the second thin-film transistor is in an on state.

15. The method according to claim 14, wherein the step of controlling brightness of the light-emitting element based on time when the first power voltage is applied as a high voltage when the second thin-film transistor is in an on state comprises a step of dividing one frame related to brightness of the light-emitting element into a plurality of sub-frames, determining the number of sub-frames operated by controlling time when the first power voltage is applied as a high voltage, and controlling brightness of the light-emitting element according to the determined number of sub-frames.

16. A method of driving a display pixel circuit using pulse width modulation (PWM) driving based on a plurality of driving elements, wherein each of the driving elements comprises a first gate electrode and a second gate electrode and has a dual gate structure,
wherein at least one of a first gate-insulating film of the first gate electrode and a second gate-insulating film of the second gate electrode is formed of a ferroelectric material and has ferroelectric properties, and
the method comprises a step of removing ferroelectric properties from any one of the driving elements based on a ground voltage to drive the driving element as a volatile switching element and drive another driving element as a non-volatile driving element based on ferroelectric properties.

17. The method according to claim 16, wherein the first gate-insulating film is formed of a non-ferroelectric material comprising silicon dioxide (SiO₂) or a ferroelectric material comprising at least one of hafnium oxide (HfOₓ), hafnium zirconium oxide (HZO), and zirconium oxide (ZrOₓ), and
the second gate-insulating film is formed of a non-ferroelectric material comprising silicon dioxide (SiO₂) or a ferroelectric material comprising at least one of hafnium oxide (HfOₓ), hafnium zirconium oxide (HZO), and zirconium oxide (ZrOₓ).

18. The method according to claim 16, wherein the driving elements comprise a first thin-film transistor and a second thin-film transistor.

19. The method according to claim 18, wherein any one of the first thin-film transistor and the second thin-film transistor comprises a substrate;
a buffer-insulating film formed on the substrate;
a first gate electrode formed on the buffer-insulating film;
a first gate-insulating film formed on the first gate electrode;
a semiconductor layer formed on the first gate-insulating film;
a second gate-insulating film formed on the semiconductor layer;
a second gate electrode formed on the second gate-insulating film;
an interlayer insulating film formed on the second gate electrode, the semiconductor layer, and the first gate-insulating film to expose a source region and drain region of the semiconductor layer;
a source electrode formed on the interlayer insulating film and electrically connected to the source region; and
a drain electrode formed on the interlayer insulating film and electrically connected to the drain region.

20. The method according to claim 19, wherein a second gate electrode of the first thin-film transistor is connected to a ground terminal to remove ferroelectric properties of a second gate-insulating film of the first thin-film transistor based on the ground voltage, and thus the first thin-film transistor has no memory characteristics and operates as the volatile switching element, and
a second gate electrode of the second thin-film transistor is connected to a source electrode of the first thin-film transistor so that the second thin-film transistor has non-volatile memory characteristics due to ferroelectric properties of a second gate-insulating film of the second thin-film transistor, and thus the second thin-film transistor operates as the non-volatile driving thin-film transistor.
